(19) United States
(12) Patent Application Publication
(10) Pub. No.: US 2009/0111210 A1
(43) Pub. Date: Apr. 30, 2009

(54) Method for Organic Semiconductor Material Thin-Film Formation and Process for Producing Organic Thin Film Transistor

(76) Inventors: Reiko Obuchi, Tokyo (JP); Katsura Hirai, Tokyo (JP); Chiyoko Takemura, Tokyo (JP)

Correspondence Address: COHEN, PONTANI, LIEBERMAN & PAVANE LLP, 551 FIFTH AVENUE, SUITE 1210, NEW YORK, NY, 10176, US

(21) Appl. No.: 11/922,466

(22) PCT Filed: May 23, 2006
(86) PCT No.: PCT/JP2006/310177

§ 371 Date: Dec. 18, 2007

(30) Foreign Application Priority Data
Jun. 21, 2005 (JP) 2005-180568

(51) Int. Cl. H01L 51/30

(52) U.S. Cl. 438/99; 257/E51.024

(57) ABSTRACT

A method for the formation of an organic semiconductor material film having improved mobility on a substrate, and a process for producing an organic thin film transistor which can develop high performance by utilizing the method. The production process of an organic thin film transistor utilizes the method for organic semiconductor material film formation, comprising coating an organic semiconductor material-containing liquid onto a surface of a substrate to form a semiconductor material thin film. The method for organic semiconductor material thin film formation is characterized in that, when the surface free energy of the surface of the substrate is γ_{S}=γ_{S}^{d}+γ_{S}^{p}+γ_{S}^{h} (wherein γ_{S}^{d}, γ_{S}^{p}, and γ_{S}^{h} each represent a non-polar component, a polar component, and a hydrogen bond component of the surface free energy of the solid surface based on the Young-Fowkes equation), and a surface free energy of a solvent in the aforesaid liquid is represented by γ_{L}=γ_{L}^{d}+γ_{L}^{p}+γ_{L}^{h} (wherein γ_{L}^{d}, γ_{L}^{p}, and γ_{L}^{h} each represent a non-polar component, a polar component, and a hydrogen bond component of the surface free energy of liquid based on the Young-Fowkes equation), γ_{S}^{h}−γ_{L}^{h} value is in the range of −5 to 20 (mN/m) and hydrogen bond component γ_{S}h is 0<γ_{S}^{h}<20 (mN/m).

### BACKGROUND OF THE INVENTION

1. Technical Field

The present invention relates to a method for forming a thin organic semiconductor material film on a substrate and a method for producing an organic thin-film transistor employing the aforesaid method for forming the thin organic semiconductor material film.

2. Background

In recent years, various organic thin-film transistors, in which organic semiconductors are employed as a semiconductor channel, have been investigated. Organic semiconductors are easily processed compared to inorganic semiconductors and also exhibit high affinity to a support, whereby they have received attention as a thin-film device.

Methods for forming a thin organic semiconductor film are represented by the method employing vapor deposition, and various methods are employed depending on characteristics of materials. Of these, organic semiconductor materials are characterized in that it is possible to easily prepare a thin film via a normal pressure process (being a wet process) such as coating or ink-jet printing in which a solution or a liquid composition is applied onto a substrate.

Under such situations, made have been many trials to obtain organic semiconductor film of a high carrier mobility, which equals silicon.

For example, in Patent Document 1, during trial to prepare a thin organic semiconductor film employing a solution layer lamination, reinforcement of polymer orientation via an oriented film is attempted.

Further, in Patent Document 2, a method is disclosed in which liquid crystalline materials are employed as an organic semiconductor material solvent, and an organic semiconductor layer having the predetermined molecular orientation is formed by applying organic semiconductor materials onto the surface which has been subjected to an orientation treatment.

Still further, in Non-patent Document 1, a thin organic semiconductor film or an organic semiconductor layer exhibiting high carrier mobility is formed in such a manner that a thiophene polymer solution exhibiting high mobility is employed and coating is carried out while solvents are dried.

Further, in some investigations, the relationship between the surface energy of a substrate, onto which a solution is applied, and the mobility of the resulting organic semiconductor material layer is noted. In Non-patent Document 2, for example, description is made in which, in a pentacene deposition film, the lower the surface energy on the substrate side is, the higher the mobility of the resulting thin pentacene film is.

The carrier mobility in an organic semiconductor layer is determined depending on crystals in the formed organic semiconductor material film or the molecular arrangement such as a π stack of the organic semiconductor material structure. Consequently, orientation during the coating or drying process is important. However, at present, it is difficult for many organic semiconductor materials to enhance performance such as an increase in carrier mobility of the formed semiconductor material film, via only regulation of the surface energy of the substrate onto which the semiconductor solution, as described above, is applied.
Patent Document 1: International Patent Publication Open to Public Inspection No. 01/47043 Pamphlet
Patent Document 2: Japanese Patent Publication Open to Public Inspection (herein after referred to as JP-A) No. 2004-31458
Non-patent Document 1: JACS 2004, 126, 3378
Non-patent Document 2: Synthetic Metals 148 (2005) 75-79

### DESCRIPTION OF THE INVENTION

### Problems to be Solved

Accordingly, the present invention relates to a method for forming, on a substrate, an organic semiconductor material film which results in enhanced mobility and patterning accuracy via simultaneous regulation of the surface energy on the substrate side as well as the surface energy of the organic semiconductor material solution. Further, the present invention relates to a production method of the organic thin-film transistor exhibiting high performance by employing the above methods.

### Technical Means to Solve the Problem

The above problems are overcome by the following means.
(1) In a method for forming a thin semiconductor material film by coating a liquid composition containing organic semiconductor material onto a surface of a substrate, the method for forming a thin organic semiconductor material film is characterized in that when the surface free energy of the above substrate surface is represented by Γ_{S}=γ_{S}^{d}+γ_{S}^{p}+γ_{S}^{h} (wherein γ_{S}^{d}, γ_{S}^{p}, and γ_{S}^{h} each represent the non-polar component, the polar component, and the hydrogen bond component of the surface free energy of the solid surface based on the Young-Fowkes equation), and the surface free energy of solvents in the aforesaid liquid is represented by γ_{L}=γ_{L}^{d}+γ_{L}^{p}+γ_{L}^{h} (wherein γ_{L}^{d}, γ_{L}^{p}, and γ_{L}^{h} each represent the non-polar component, the polar component, and the hydrogen bond component of the surface free energy of liquid based on the Young-Fowkes equation), γ_{S}^{h}−γ_{L}^{h} value is in the range of −5 to 20 (mN/m) and hydrogen bond component γₛh is 0<γ_{S}^{h}<20 (mN/m).
(2) The thin organic semiconductor material film forming method described in (1) above, which is characterized in that the surface of the aforesaid substrate has been subjected to a surface treatment.
(3) The thin organic semiconductor material film forming method described in (1) or (2) above, which is characterized in that the hydrogen bond component of the surface free energy of the substrate surface γₛ^{h} is 0<γ_{S}^{h}<15 (mN/m)
(4) The thin organic semiconductor material film forming method described in any one of (1)-(3) above, which is characterized in that the aforesaid surface treatment employs a silane coupling agent.
(5) The thin organic semiconductor material film forming method described in any one of (1)-(4) above, which is characterized in that the solvent in the aforesaid liquid composition containing organic semiconductor material is a non-halogenated solvent.
(6) The thin organic semiconductor material film forming method, described in any one of (1)-(5) above, which is characterized in that a weight average molecular weight of the aforesaid organic semiconductor material is at most 5,000.
(7) An organic thin-film transistor production method which is characterized in that the thin organic semiconductor material film forming method described in any one of (1)-(6) above, in which the aforesaid organic semiconductor material is a compound containing a thiophene ring, is employed.
(8) The organic thin-film transistor production method, described in (7) above, which is characterized in that the aforesaid organic semiconductor material is a compound having an alkylthiophene ring.

### Advantage of the Invention

According to the present invention, a thin organic semiconductor material film of enhanced carrier mobility is obtained and an organic thin-film transistor of a high efficiency is obtained.

### BRIEF DESCRIPTION OF THE DRAWINGS

FIG. 1 is a view showing a construction example of the organic thin-film transistor according to the present invention.

FIG. 2 is one example of an approximately equivalent circuit of an organic TFT sheet according to the present invention.

### DESCRIPTION OF THE NUMERALS

1 organic semiconductor layer
2 source electrode
3 drain electrode
4 gate electrode
5 insulation layer
6 support
7 gate bus line
8 source bus line
10 organic TFT sheet
11 organic TFT
12 output element
13 storage condenser
14 vertical driving circuit
15 horizontal driving circuit

### OPTIMAL EMBODIMENT OF THE INVENTION

The most preferred embodiments to practice the present invention will now be detailed; however the present invention is not limited thereto.

It is possible to provide a preferably driving organic thin-film transistor employing the thin organic semiconductor material film forming method of the present invention.

Organic thin-film transistors are mainly divided into a top gate type which has a support having thereon a source electrode and a drain electrode which are connected by an organic semiconductor layer, further having thereon a gate electrode via a gate insulating layer, as well as a bottom gate type which has a support initially having thereon a gate electrode, further having thereon a source electrode and a drain electrode which are connected by organic semiconductor channel via a gate insulating layer.

Organic thin-film transistors prepared by the organic semiconductor film forming method according to the present invention may be either the above top gate type or the bottom gate type, and further, their embodiments are not particularly limited.

Further, any appropriate organic compounds may be selected to form the organic semiconductor film which constitutes an organic semiconductor channel (being an active layer) in thin-film transistors, employed in the process of the present invention, as long as they function as a semiconductor. However, when relatively low molecular weight compounds are employed, their weight average molecular weight is preferably at most 5,000.

As a low-molecular weight compound, typically, there is a compound such as pentacene, and specifically, for example, there are the pentacene having a substituent group described in WO03/16599, WO03/28125, U.S. Pat. No. 6,690,029, and Japanese Patent Application 2004-107216 and the pentacene precursor described in US2003-136964.

Further, as an organic semiconductor material with a lower-molecular weight than the aforementioned molecular weight, a compound containing two or more heterocycles in the molecular structure is preferable and specifically, a compound in which the aforementioned heterocycles are thiophene rings may be cited as a preferable compound. The concerned thiophene ring may have a substituent group such as the alkyl group or may be a non-substituent ring, though it contains preferably the thiophene ring having a substituent group in each molecule, and it contains more preferably both the thiophene ring having a substituent group and non-substituent thiophene ring. Furthermore, two or more thiophene rings are preferably connected and the number of connected thiophene rings is preferably 2 to 10.

Further, according to the present invention, an oligomer having a molecular weight lower than the average molecular weight 5,000 is a preferable compound as an organic semiconductor material. As an oligomer preferably used specifically in the present invention, the thiophene oligomer may be cited.

As a thiophene oligomer preferably used in the present invention, it is preferable to include a thiophene oligomer having a partial structure in which at least two repeating units of the thiophene ring having a substituent group and repeating units of the non-substituent thiophene ring are respectively connected and set the number of thiophene rings included in the thiophene oligomer within the range from 8 to 40. The number of rings of the above mentioned thiophene rings are preferably from 8 to 20. More preferably the thiophene oligomer has a partial structure represented by following Formula (1).

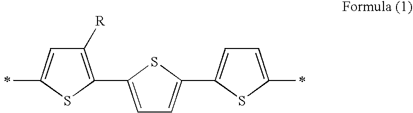

In the formula, a symbol R represents a substituent.

### <<Thiophene Oligomer Represented by Formula (1)>>

The thiophene oligomer represented by Formula (1) used in the present invention will be described.

Examples of a substituent represented by R in Formula (1) include: an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group and a pentadecyl group); a cycloalkyl group (for example, a cyclopentyl group and a cyclohexyl group); an alkenyl group (for example, a vinyl group and an allyl group); alkynyl groups (for example, an ethynyl group and a propargyl group); an aryl group (for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group and a biphenylyl group); an aromatic heterocyclic group (for example, a furyl group, a thienyl group, a pyridyl group, a pyridazyl group, a pyrimidyl group, a pyrazyl group, a triazyl group, an imidazolyl group, a pyrazolyl group, a thiazolyl group, a benzimidazolyl group, a benzoxazolyl group, a quinazolyl group, and a phthalazyl group), a heterocyclic group (for example, a pyrrolidyl group, an imidazolydyl group, a morpholyl group, and an oxazolydyl group), an alkoxy group for example, a methoxy group, an ethoxy group, a propyloxy group, a pentyloxy group, a hexyloxy group, an octyloxy group, and a dodecyloxy group), a cycloalkoxy group (for example, a cyclopentyloxy group and a cyclohexyloxy group), an aryloxy group (for example, a phenoxy group and a naphthyloxy group), an alkylthio group (for example, a methylthio group, an ethylthio group, a propylthio group, a pentylthio group, a hexylthio group, an octylthio group, and a dodecylthio group), a cycloalkylthio group (for example, a cyclopentylthio group and a cyclohexylthio group), an arylthio group (for example, a phenylthio group and a naphthylthio group), an alkoxycarbonyl group (for example, a methyloxycarbonyl group, an ethyloxycarbonyl group, a butyloxycarbonyl group, an octyloxycarbonyl group, and a dodecyloxycarbonyl group), an aryloxycarbonyl group (for example, a phenyloxycarbonyl group and a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, and a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecylcarbonyl group, a phenylcarbonyl group, a naphthylcarbonyl group, and a pyridylcarbonyl group), an acyloxy group (for example, an acetyloxy group, an ethylcarbonyloxy group, a butylcarbonyloxy group, an octylcarbonyloxy group, a dodecylcarbonyloxy group, and a phenylcarbonyloxy group), an amido group (for example, a methylcarbonylamino group, an ethylcarbonylamino group, a dimethylcarbonylamino group, a propylcarbonylamino group, a pentylcarbonylamino group, a cyclohexylcarbonylamino group, a 2-ethylhexylcarbonylamino group, an octylcarbonylamino group, a dodecylcarbonylamino group, a phenylcarbonylamino group, and a naphthylcarbonylamino group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecylaminocarbonyl group, a phenylaminocarbonyl group, a naphthylaminocarbonyl group, and a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, and a 2-pyridylaminoureido group), a sulfinyl group (for example, a methylsulfonyl group, an ethylsulfonyl group, a butylsulfonyl group, a cyclohexylsulfinyl group, a 2-ethylhexylsulfinyl group, a dodecylsulfinyl group, a phenylsulfonyl group, a naphthylsulfinyl group, and a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, and a dodecylsulfonyl group), an arylsulfonyl group (for example, a phenylsulfonyl group, a naphthylsulfonyl group, and a 2-pyridylsulfonyl group), an amino group (for example, an amino group, an ethylamino group, a dimethylamino group, a butylamino group, a cyclopentylamino group, a 2-ethylhexylamino group, a dodecylamino group, an anilino group, a naphthylamino group, and a 2-pyridylamino group), an halogen atom (for example, a fluorine atom, a chlorine atom, and a bromine atom), a fluorinated hydrocarbon group (for example, a fluoromethyl group, a trifluoromethyl group, a pentafluoroethyl group), a cyano group, a silyl group (for example, a trimethylsilyl group, a triisopropylsilyl group, a triphenylsilyl group, and a phenyldiethylsilyl group).

These substituents may further be substituted with the above substituents, and a plurality of the above substituents may join to form a ring.

Of these, the preferred substituent is an alkyl group, the more preferred one is an alkyl group having 2-20 carbon atoms, but the most preferred one is an alkyl group having 4-12 carbon atoms.

### <<Terminal Group of Thiophene Oligomer>>

The terminal group of a thiophene oligomer employed in the present inventions will now be described.

It is preferable that the terminal group of the thiophene oligomers employed in the present invention has no thienyl group. Listed as preferred groups in the above terminal group are an aryl group (for example, a phenyl group, a p-chlorophenyl group, a mesityl group, a tolyl group, a xylyl group, a naphthyl group, an anthryl group, an azulenyl group, an acenaphthenyl group, a fluorenyl group, a phenanthryl group, an indenyl group, a pyrenyl group, and a biphenylyl group), an alkyl group (for example, a methyl group, an ethyl group, a propyl group, an isopropyl group, a tert-butyl group, a pentyl group, a hexyl group, an octyl group, a dodecyl group, a tridecyl group, a tetradecyl group, and a pentadecyl group), a halogen atom (for example, a fluorine atom, a chlorine atom, and a bromine atom).

### <<Characteristics of Steric Structure of Repeating Unit of Thiophene Oligomer>>

It is preferable that thiophene oligomers employed in the present invention have no head-to-head structure. In addition, it is more preferable to have a head-to-tail structure or a tail-to-tail structure.

With regard to the head-to-head structure, the head-to-tail structure and the tail-to-tail structure according to the present invention, reference can be made, for example, on pages 27-32 of “π Denshi Kei Yuki Kotai (π Electron Based Organic Solids” (edited by the Chemical Society of Japan, published by Gakkai Shuppan Center, 1998) and to Adv. Mater. 1998. 10, No. 2, pages 93-116. Each of the structural characteristics will now be specifically described.

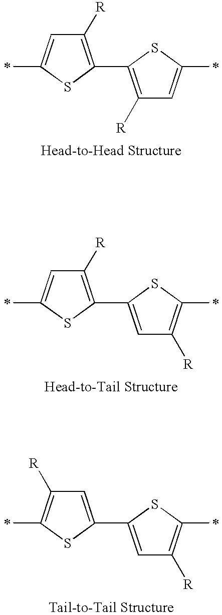

R is the same as R in the Formula (1).

Specific examples of the thiophene oligomers employed in the present invention are listed below; however, the present invention is not limited thereto.

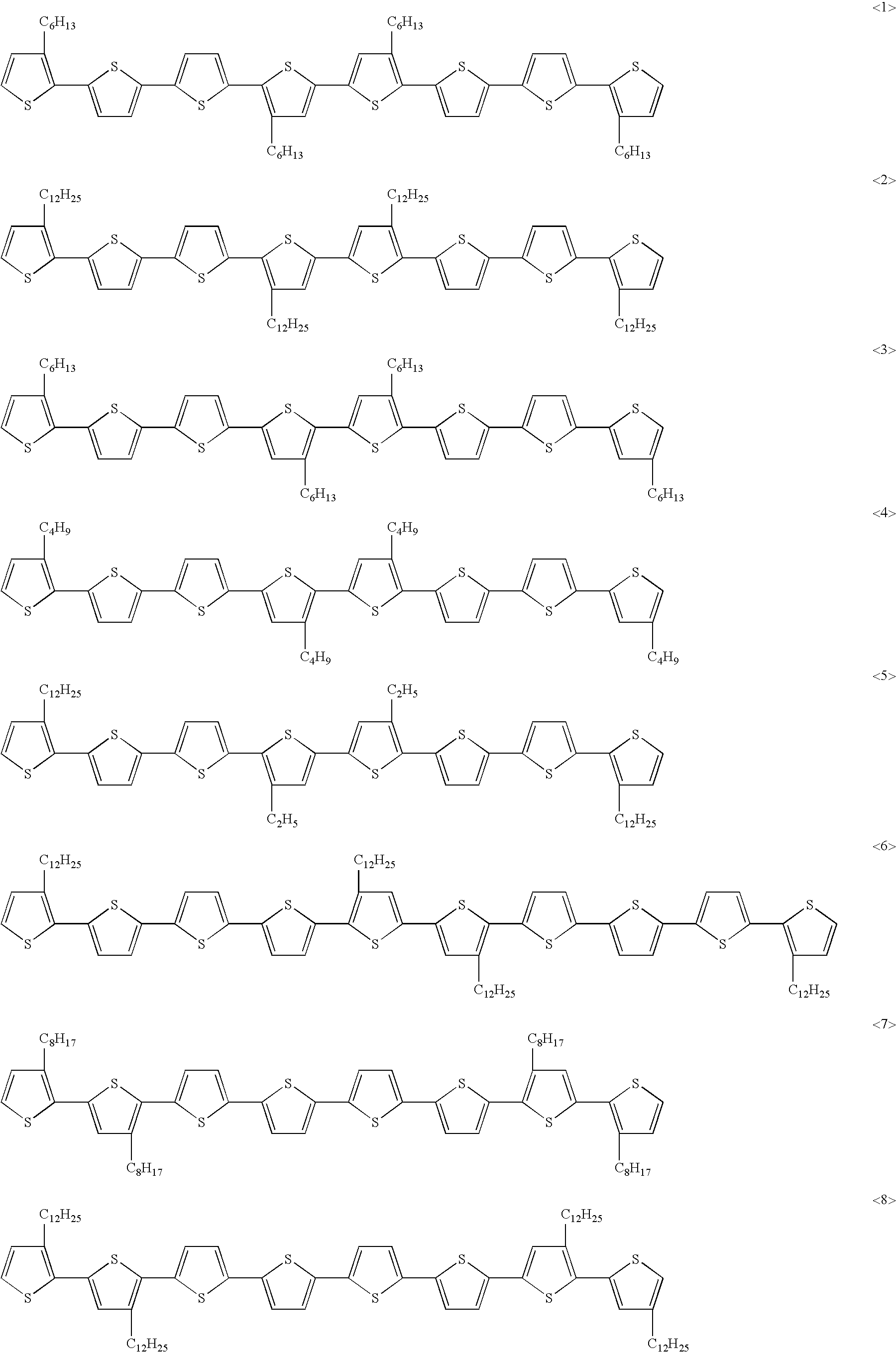

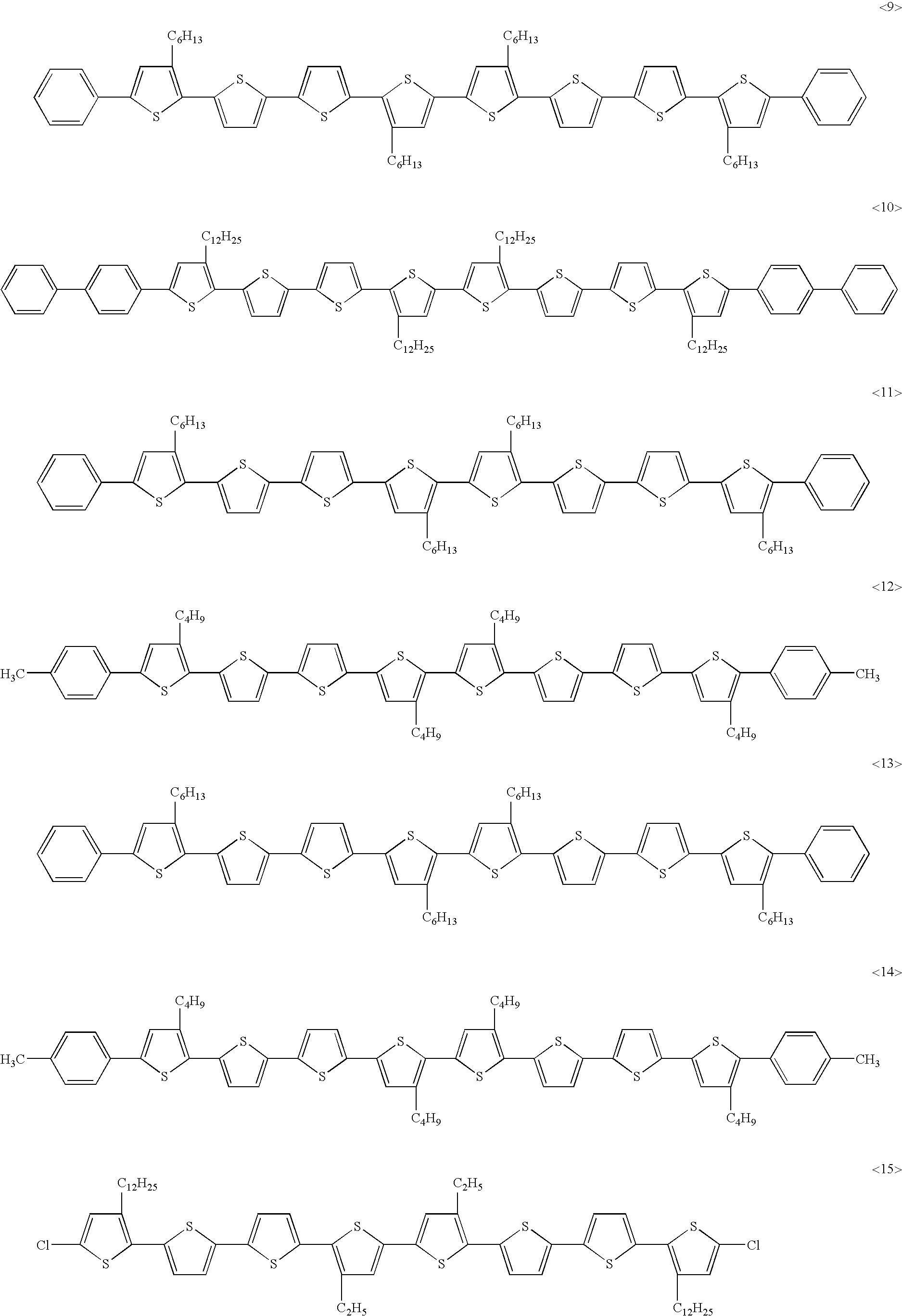

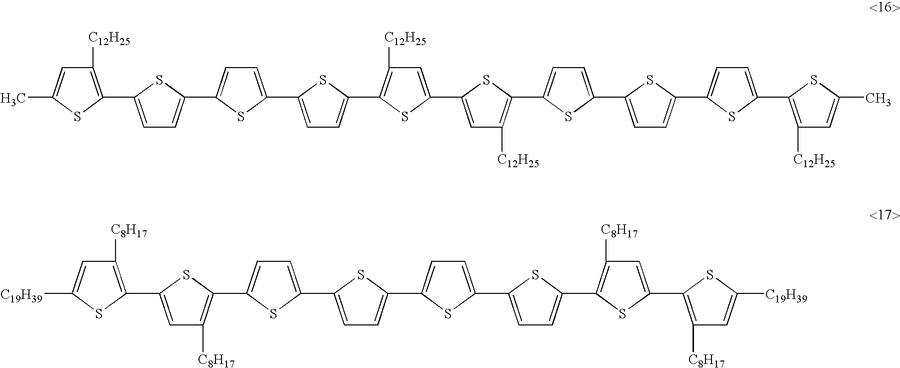

The synthetic methods of these thiophene oligomer are described in Japanese Patent Application No. 2004-172317 (filed on Jun. 10, 2004) filed by the inventors of the present invention.

Further, in the present invention, employed as organic semiconductor materials may be functionalized pentacenes such as TIPS pentacene, described in Advanced Materials, 15, No. 23, 2009-2011.

In the present invention, an organic semiconductor solution is applied onto a substrate via coating or an ink-jet method, whereby by a normal pressure process, a thin semiconductor material film is more easily prepared than vapor deposition. For example, in the coating method, the above organic semiconductor materials are dissolved in solvents and by applying the resulting solution onto a substrate such as a silicon wafer carrying an oxidized film, followed by drying, it is possible to prepare a thin organic semiconductor material film.

The carrier mobility of a thin organic semiconductor material film is determined via the molecular arrangement of semiconductor material crystals or organic semiconductor material structure such as such as π-stack. However, occasionally, it is difficult to carry out desired reproduction of the highly oriented structure via applying an organic semiconductor material solution onto a substrate (for example, via coating or an ink-jet method), followed by drying, because various factors are involved, which include affinity to the substrate, the surface state of the substrate, affinity to the substrate surface, and the intermolecular force among organic semiconductor molecules (or oligomers or polymers).

The present invention was achieved by discovering the following. During preparation of a thin organic semiconductor film, by applying an organic semiconductor material solution onto a substrate, the surface free energy of a substrate surface onto which a semiconductor solution was applied and the surface free energy (namely the surface tension) of solvents, in which organic semiconductor materials were dissolved or dispersed were regulated so that each relationship was regulated in the range which satisfied predetermined conditions. Thus, a thin organic semiconductor material film forming method was discovered in which carrier mobility of the resulting thin organic semiconductor material film was high, and even on the substrate surface of a high insulation and hydrophorbicity, it was possible to carry out highly detailed and accurate patterning. The present invention relates to an organic semiconductor material film forming method characterized in that by controlling the correlation between the surface free energy on the insulator surface on which the thin organic semiconductor material film is formed and the surface free energy of the organic semiconductor solution, a thin semiconductor material film is formed by applying the organic semiconductor solution onto the above insulator surface.

For example, in the case of bottom-gate type organic thin-film transistors, the insulator surface, on which an organic semiconductor material thin film is to be formed, is one of a silicon wafer substrate carrying an oxidized film. A thin organic semiconductor material film is formed on the above substrate and a source electrode and a drain electrode are further formed, followed by connection to the semiconductor layer, whereby it is possible to form a bottom-gate type organic thin-film transistor. The silicon wafer also works as a gate and the oxidized film (being the oxidized silicon film) constitutes a gate insulation layer.

Further, in the case of the top-gate type, for example, initially an organic semiconductor layer is formed on a support which is an insulator, whereby a source electrode connected to a drain electrode is formed. Further, a gate electrode is formed thereon through a gate insulation layer, whereby an organic thin-film transistor is formed. In this case, initially an organic semiconductor solution is applied and the surface of the support (being the insulator) which forms a thin organic semiconductor film (layer) constitutes the insulator surface.

In any case, a process is required to form a thin organic semiconductor material film of high carrier mobility on each substrate, namely on the surface of an insulator which is employed as a substrate. Further, in order to form a TFT sheet having a minute structure, it is essential that these organic semiconductor material solutions are capable of being applied onto the substrate to be highly detailed under high patterning accuracy.

In the present invention, in a forming method of an organic semiconductor material film in which a thin semiconductor material film is formed on a substrate by applying an organic semiconductor solution onto the surface of these substrates; in a forming method of an organic semiconductor material film in which a thin semiconductor film is formed on a substrate by applying a liquid composition containing organic semiconductor materials onto an insulator surface, when the surface free energy on the surface of the above insulator is represented by γ_{S}=γ_{S}^{d}+γ_{S}^{p}+γ_{S}^{h} (wherein γ_{S}^{d}, γ_{S}^{p}, and γ_{S}^{h} each represent a non-polar component, a polar component, and a hydrogen bond component of a solid surface, respectively, each of which is based on Young-Fowkes equation), and further, when the surface free energy of solvents in the above liquid composition is represented by γ_{L}=γ_{L}^{d}+γ_{L}^{p}+γ_{L}^{h} (wherein γ_{L}^{d}, γ_{L}^{p}, and γ_{L}^{h} each represent a non-polar component, a polar component, and a hydrogen bond component of surface free energy of the liquid, respectively, each of which is based on Young-Fowkes equation);

by regulating γ_{S}^{h}−γ_{S}^{h} value within the range of −5 to 20 mN/m and by regulating hydrogen bond component γ_{S}^{h} of surface free energy on the substrate surface to satisfy the relationship of 0<γ_{S}^{h}<20 mN/m, it was discovered that it was possible to prepare a very smooth organic semiconductor material film which exhibited large carrier mobility and high coating accuracy.

As described in above Non-patent Document 2, it is preferable that the surface energy of the substrate is relatively low. When hydrogen bond component value γ_{S}^{h} of the surface energy of the substrate is at least 20 mN/m, as described above, it is difficult to prepare a smooth film of high coating accuracy.

With regard to the surface energy of the substrate, specifically in order to decrease the hydrogen bond component, it is preferable that the substrate surface has been subjected to a surface treatment.

Surface treatment, as described herein, refers to a treatment which decreases the surface energy of the substrate or changes the surface roughness. Namely, when the surface energy of the substrate is sufficiently low so that mutual interaction with semiconductor materials becomes not so great, mutual interaction between the molecules of the semiconductor materials is significantly generated, whereby it is assumed that the molecules of organic semiconductor materials are preferably oriented. Specifically, as the hydrogen bond component of the surface energy on the substrate surface side decreases, the organic semiconductor materials are easily oriented. This suggests that the orientation of the organic semiconductor materials is significantly affected.

In the present invention, except for low surface energy of the substrate surface, in order to promote the molecular arrangement and orientation, such as π stack of organic semiconductor materials on the substrate, it is effective to select each substrate surface and solvents employed in the solution so that difference γ_{S}^{h}−γ_{L}^{h} is in the range of −5 to 20 mN/m, wherein γ_{S}^{h} represents the hydrogen bond component of the surface free energy on the surface of an insulator (being a solid) which is a substrate and γ_{L}^{h} represents the hydrogen bond component of the surface free energy of solvents constituting a liquid composition containing organic semiconductor materials which will be applied onto the insulator surface via coating or an ink-jet method.

It is possible to determine the surface free energy of the insulator solid as described in the present invention via the following method.

Namely, the contact angle, of each of three standard liquids, namely hexane, methylene iodide and water, each of the surface free energy being known, to the solid surface to be measured is determined five times employing a contact angle meter CA-V, produced by Kyowa Interface Science Co., Ltd. Subsequently, the determined values are averaged and each of the average contact angles is obtained. Determination is carried out in an ambience of 20° C. and 50% relative humidity.

Subsequently, it is possible to calculate three components of the surface free energy of the above solid, based on the following Young-Dupre equation and expanded Fowkes equation.

Young-Dupre Equation

W_{SL}=γ_{L}(1+cos θ)
W_{SL}: adhesion energy between the liquid and solid
γ_{L}: surface free energy of the liquid
θ: liquid/solid contact angle

Expanded Fowkes Equation

W_{SL}=2{(γ_{S}^{d}γ_{L}^{d})^{1/2}+(γ_{S}^{p}γ_{L}^{p})^{1/2}+(γ_{S}^{h}γ_{L}^{h})^{1/2}}
γ_{L}=γ_{L}^{d}+γ_{L}^{p}+γ_{L}^{h}: surface free energy of the liquid
γₛ=γ_{S}^{d}+γ_{S}^{p}+γ_{S}^{h}: surface free energy of the solid

γ_{d}, γ^{p}, γ^{h}: variance, dipole moment, and hydrogen bond component of surface free energy

Accordingly, the surface free energy of n-hexane is already known as

γ_{L}(1+cos θ)=2{(γ_{S}^{d}γ_{L}^{d})^{1/2}+(γ_{S}^{p}γ_{L}^{p})^{1/2}+(γ_{S}^{h}γ_{L}^{h})^{1/2}}.

Since the three components, namely γ_{L}^{d}, γ_{L}^{p}, and γ_{L}^{h}, are found (γ_{L}^{d}=18.4 mN/m, and γ_{L}^{p} and γ_{L}^{h}=0), γ_{S}^{d} of the surface of an insulator is obtained.

Further, contact angle θ of water and the above three components of the surface energy of water are known (γ_{L}^{d}−29.1 mN/m, γ_{L}^{p}=4.0 mN/m and γ_{L}^{h}=0), whereby γ_{S}^{p} of the surface of the insulator is obtained based on these values.

Still further, contact angle θ of water and of the above three components of the surface energy of water are known (γ_{L}^{d}=29.1 mN/m, γ_{L}^{p}=1.3 mN/m, and γ_{L}^{h}=42.4 mN/m), whereby γ_{S}^{h} of the surface of the insulator is obtained based on those values.

As noted above, it is possible to obtain the surface free energy of a solid, based on the surface free energy of the above three solvents and each respective contact angles. The combination of n-hexane, methylene iodide, and water is not always limited, and other combinations may be chosen. However, the above surface free energy of n-hexane is composed only of the variance term and is easily calculated.

The surface free energy of these solvents may be referred to literature. It is possible to employ data (data at 20° C. are employed) described, for example, on page 33 of Toshio Ishii, Shinjun Koishi, and Mitsuo Kakuta, “Nure Gijutsu Handbook—Kiso•Sokutei Hyoka Data—(Wetting Technology Handbook—Basis•Measurement Evaluation Data—)”, and on pages 176-177 of Yuji Harasaki “Coating no Kiso Kagaku (Basic Science of Coating)” Maki Shoten. Representative data are listed in Table 2 of Examples.

Further, it is possible to find, in the above reference, the representative surface energy of those solvents. It is possible to obtain the surface energy which is not found in the literature by employing the above formula in which solid polymers, namely polyethylene (the surface energy components only composed of γ_{S}^{d}=35.6 mN/m and γ_{S}^{p}, and γ_{S}^{h}=0), polyethylene tetrafluoride (PTFE) (γ_{S}^{d}=19.4 mN/m, γ_{S}^{p}=2.1 mN/m, and γ_{S}^{h}=0) and polyvinylidene fluoride (three components of γ_{S}^{d}=27.6 mN/m, γ_{S}^{p}=9.1 mN/m, and γ_{S}^{h}=3.5 mN/m), each of which surface energy is known, are employed. Namely, it is possible to obtain the surface energy in the same manner as above by determining the contact angle of a solvent on the above three polymer substrates.

According to the above method, it is possible to obtain the surface tension, namely surface free energy of solvents which are hardly found in the literature.

In the present invention, when a mixed solvent is employed, the surface free energy of the above mixed solvent is obtained in such a manner that the surface free energy of each component of each solvent is weight-averaged based on each solvent ratio (being the mol ratio).

In the present invention, it is required that difference γ_{S}^{h}−γ_{L}^{h}, between hydrogen bond component γ_{S}^{h} of surface free energy on the surface of an insulator (being a solid) which is a substrate and hydrogen bond component γ_{L}^{h} of surface free energy of solvents constituting a liquid composition containing organic semiconductor materials, which is applied onto the surface of the insulator via coating or an ink-jet method, is within the range of −5 and 20 mN/m. The reasons for the above range being preferred are assumed to be as follows.

When an organic semiconductor material solution is applied onto a substrate to form a thin film, it is assumed that as the surface free energy of solvents increases, mutual interaction, for example, between the molecules of the organic semiconductor materials and solvents, increases, whereby the molecular stack of the organic semiconductor materials is readily affected. Specifically, when the hydrogen bond component of surface free energy of the organic semiconductor material solution or solvents constituting the solution is large, the molecular orientation of the organic semiconductor materials is readily affected, and thereby, a state (formation of a structure such as a π-stack, in which, for example, molecules stand up on a substrate) tends to be formed, whereby a thin organic semiconductor film of a high carrier mobility tends to form.

However, when the surface free energy of the organic semiconductor material solution or solvents constituting the solution is excessively high, during application of the organic semiconductor material solution onto the surface of a solid, wettability of the substrate surface to the organic semiconductor martial solution is degraded, resulting in difficult coating.

Of surface free energies, mutual interaction due to the hydrogen bond is large compared to dispersion force (being a non-polar term) and intermolecular interaction (being a dipole term), whereby contribution of γ_{L}^{h} and γ_{S}^{h} is assumed to be high.

Accordingly, when the above value γ_{S}^{h}−γ_{L}^{h} exceeds 20 mN/m, coatability is degraded, while when it is at most −5 mN/m, mutual interaction among the organic semiconductor material molecules is hindered, and thereby the formed molecular stack is (supposed) to be limited to a small range, whereby it is not possible to prepare a semiconductor film of high carrier mobility.

Further, when interaction between solvents which dissolve organic semiconductor materials and organic semiconductor materials, or between molecules of organic semiconductor materials, is high, during the process in which a semiconductor molecular film is formed while drying, the solution on the substrate is not easily spread, whereby it is possible to carry out coating of high accuracy, enabling achievement of highly detailed and accurate patterning.

Consequently, according to the present invention, it becomes possible to prepare a semiconductor film of high carrier mobility via a method in which an organic semiconductor material solution is applied onto a highly insulating substrate, employing a wet system method such as a coating method or an ink-jet method.

Further, in order to achieve the above, of variance component γ_{S}^{d}, polar component γ_{S}^{p}, and hydrogen bond component γ_{S}^{h} of solid surface free energy, hydrogen bond component γ_{S}^{h} of the surface of a substrate is required to be less than 20 mN/m.

In order to decrease the solid surface free energy on the surface of a substrate, it is preferable that the surface of the substrate has been subjected to a surface treatment. Further, a surface which exhibits low interaction is preferred so that hydrogen bond component γ_{S}^{h} of solid surface free energy is preferably less than 15 mN/m (more than 0), but is more preferably less than 10 mN/m.

Based on these methods of the present invention, it is possible to form an organic semiconductor material film of high orientation and high carrier mobility on the hydrophobic and insulating surface exhibiting low surface free energy. Specifically, when applied to the above thiophene based compounds, or thiophene based oligomers, especially to alkylthiophene oligomers of a weight average molecular weight of at most 5,000, it is possible to prepare a film of high mobility.

In the present invention, when a thin organic semiconductor film is formed by applying a liquid dissolving the organic semiconductor materials (specifically, a solution), onto the surface of an insulator, employing, for example, a coating method, an ink-jet method, or a printing method, as noted above, the surface of the insulator or the surface energy (i.e., surface tension) is regulated.

The organic semiconductor materials applied onto the substrate are dried along with volatilization of solvents, and after drying, a thin organic semiconductor material film is formed on the substrate. In the resulting organic semiconductor material film, orientation is enhanced via the molecular arrangement such as π stack or crystallization of the molecules of the organic semiconductor materials, whereby carrier mobility of the thin organic semiconductor materiel film is markedly enhanced.

During formation of organic thin-film transistors, since these organic semiconductor material films are formed on a substrate carrying a gate insulation film such as a highly hydrophobic insulating film such as a thermally oxidized silicon film, solvents which dissolve the above organic semiconductor materials may be selected so that the surface energy of the above substrate having the above insulator surface and the surface energy of the employed solvents satisfy the above relationship. Further, solvents are preferred which exhibit affinity to the applied surface. Examples of such solvents include aromatic hydrocarbons such as toluene, chain aliphatic hydrocarbons such as hexane or butane, cyclic aliphatic hydrocarbons such as cyclohexane or cyclopentane, aliphatic hydrocarbons, halogenated hydrocarbons such as chloroform or 1,2-dichloroetahne, chain ethers such as diethyl ether or diisopropyl ether, cyclic ethers such as tetrahydrofuran or dioxane, and ketones such as acetone or methyl ethyl ketone. Further, these solvents may be blended. Still further, in order to promote dissolution of organic semiconductor materials, other solvents which exhibit high solubility for the organic semiconductor materials may be blended, as one component of the mixed solvent, in an amount which does not adversely affect the above effects, namely in the range of at most 30% by weight, but preferably at most 10% by weight.

In these cases, it is preferable to select and employ those which satisfy the above relationship between free energies of the solvents constituting the solvents and the surface of the insulator, depending on the surface of the insulator (being a substrate carrying the same).

The content of organic semiconductor materials in these solvents varies depending on the type of employed solvents or selection of organic semiconductor materials. However, in order to form a thin film by applying these liquid materials onto a substrate via coating, the dissolved amount of the semiconductor materials in the above materials is commonly in the range of 0.01-10.0% by weight, but is preferably in the range of 0.1-5.0% by weight. When the concentration is excessively high, it is not possible to carry out uniform spreading on the substrate, while when it is excessively low, pin holes tend to result in the coated layer due to insufficient coating solution on the substrate.

In the present invention, it is possible to form a thin organic semiconductor material film on a substrate in such a manner that an organic semiconductor material solution is applied onto the surface of an insulator (namely, onto a substrate) and subsequently dried.

Further, in the present invention, a thermal treatment may be carried out at a predetermined temperature for a predetermined period after arranging the organic semiconductor material film (layer). It is possible to further enhance, and to promote the orientation or arrangement of molecules of the organic semiconductor materials formed as above.

It is preferable to carry out the above thermal treatment below the melting point of the organic semiconductor materials. Specifically, when the organic semiconductor materials exhibit an exothermic peak during the above differential scanning colorimetric (DSC) measurement, it is preferable to carry out a treatment over a constant period in the temperature range of at most melting point—at least heating initiation. For example, the duration of heating is commonly from 10 seconds to one week, is preferably from 10 seconds to one day, but is more preferably from 10 seconds to one hour. For example, in the case of above Oligomer Compound Example (1), data determined via a differential scanning calorimeter (DSC), such as TYPE RDC2, produced by Seiko Electronic Industries Co., Ltd. exhibit an exothermic initiation temperature of 31.9° C. and a melting point of 79.0° C. The melting point of organic semiconductor materials is preferably in the range of 50-200° C.

Since a thermal treatment at a temperature above the melting point melts organic semiconductor materials, the resulting orientation or crystallized film is in a fusion state, resulting in breakdown. Further, exposure to excessively high temperature is not preferred since organic semiconductor materials themselves suffer from decomposition and modification.

It is preferable that these thermal treatments are carried out in inert gases such as nitrogen, helium or argon. Further, the pressure of these inert gases is preferably 0.7×10²-1.3×10² kPa, namely near atmospheric pressure.

In the present invention, substrates having an insulator surface, on which the organic semiconductor material film is formed, differ depending on production procedures such as the top gate-type or the bottom-gate type, described below. Specifically, in the production of bottom-gate type organic thin-film transistors, listed is a gate insulation film (being a thermally oxidized film formed on a polysilicon substrate) formed on the gate electrode. Further, in the top-gate type thin-film transistors, referred is to a substrate having an insulator surface on which the organic semiconductor material film (layer) is initially formed. In the present invention, it is preferable that the surface is prepared so that, of dispersion component γ_{S}^{d}, polar component γ_{S}^{d}, and hydrogen bond component γ_{S}^{h}, hydrogen bond of the surface free energy of the solid surface based on Young-Fowkes equation, hydrogen bond component γ_{S}^{h} satisfies the relationship of 0<γ_{S}^{h}<15 mN/m and further 0<γ_{S}^{h}<10 mN/m.

In order to realize a surface of a relatively low value of the above hydrogen bond component, for example, it is preferable that the gate insulation film is subjected to a surface treatment. Such treatments include a process in which the surface roughness of the gate insulation film is varied via polishing, an orientation process such as rubbing to form a thin film of a self-arranged type, and a surface treatment via silane coupling agents. Examples of preferred silane coupling agents include octadecyltrichlorosilane, octyltrichlorosilane, hexamethyldisilane, and hexamethyldisilazane, however the present invention is not limited thereto. Further, the silane coupling agent treatment is preferred due to a significant decrease in the surface free energy of the substrate surface.

In the present invention, the contact angle of the substrate surface, to which liquid materials containing organic semiconductor materials is applied, is determined at 20° C. and 50% relative humidity, employing contact angle meter Type CA-V or CA-DT-A, produced by Kyowa Interface Science Co., Ltd.

The thickness of the organic semiconductor layer formed as above is not particularly limited. However, in many cases, characteristics of the resulting organic thin-film transistors (TFT) markedly vary depending on the layer thickness. Further, the layer thickness differs due to semiconductor materials. The thickness is commonly at most 1 μm, but is most preferably 10-300 nm.

Further, when condensed polycyclic aromatic compounds are used as an organic semiconductor material, a so-called doping treatment may be carried out via incorporation, in the organic semiconductor layer, of not only organic semiconductor materials, but also materials which work as an acceptor which receives electrons, such as acrylic acid, acetamide, materials having a functional group such as a dimethylamino group, a cyano group, a carboxyl group, or a nitro group, benzoquinone derivatives, tetracyanoethylene and tetracyanoquinodimethane and derivatives thereof, as well as materials which work as a donor which is an electron donor, such as materials having a functional group such as an amino group, a triphenyl group, an alkyl group, a hydroxyl group, an alkoxy group, or a phenyl group, substituted amines such as phenylenediamine, anthracene, benzanthracene, substituted benzanthracenes, pyrene, substituted pyrene, carbazole and derivatives thereof, or tetrathiafulvalene and derivatives thereof.

The forming method of the organic semiconductor film according to the present invention is also useful in structure formation, such as orientation of organic semiconductor material molecules of the organic semiconductor film which is subjected to doping.

The bottom-gate type organic thin-film transistor, which is one of the preferred embodiments of the present invention, will be used as an example, and preparation of the organic thin-film transistor will be described.

The organic thin-film transistor is structured so that a gate electrode, a gate insulation film, an active layer, a source electrode, and a drain electrode are optimally arranged.

Accordingly, the organic thin-film transistor according to the present invention is formed in such a manner that, for example, after forming the gate electrode on the support, the gate insulation film is formed, and after its formation on the gate insulation film, the active layer (being the thin organic semiconductor material film (layer)) based on the above-mentioned method, each of the source and the drain electrodes is formed.

Further, for example, after forming the gate insulation film, a source and drain electrode pattern is formed, and an organic semiconductor layer is formed via patterning between the above source and drain electrodes.

As noted above, the organic semiconductor thin-film transistor according to the present invention is prepared in such a manner that the gate electrode, the gate insulation film, the thin organic semiconductor material film (layer), the source electrode, and the drain electrode are optimally arranged, if desired, via being arbitrarily subjected to patterning.

Other components which constitute the organic thin-film transistor, except for the organic semiconductor film (layer) in the present invention, will mow be described.

According to the present invention, the materials for forming the source electrode, drain electrode, and gate electrode, if they are conductive materials, are not restricted specifically and various metallic materials can be used. For example, platinum, gold, silver, nickel, chromium, copper, iron, tin, antimony, lead, tantalum, indium, palladium, tellurium, rhenium, iridium, aluminum, ruthenium, germanium, molybdenum, tungsten, tin-antimony oxide, indium-tin oxide (ITO), fluorine doped zinc oxide, zinc, carbon, graphite, glassy carbon, silver paste, carbon paste, lithium, beryllium, sodium, magnesium, potassium, calcium, scandium, titanium, manganese, zirconium, gallium, niobium, alloy of sodium and potassium, mixture of magnesium and copper, mixture of magnesium and silver, mixture of magnesium and aluminum, mixture of magnesium and indium, mixture of aluminum and aluminum oxide, and mixture of lithium and aluminum are used, though specifically, platinum, gold, silver, copper, aluminum, indium, ITO, and carbon are preferable.

As an electrode forming method, a method for forming an electrode from a conductive film formed from one of the raw materials listed above by vacuum evaporation or sputtering by the well-known photolithographic method or lift-off method and a method for etching a metallic foil such as aluminum or copper using a resist by heat transfer or ink jet may be cited.

Further, as an electrode forming method, a method for patterning a conductive fine-particle dispersed liquid or a conductive polymer solution or dispersed liquid directly by the ink jet method and a method for forming an electrode from a coated film by lithography or laser ablation may also be cited. Furthermore, a method for patterning ink containing a conductive polymer or conductive fine particles or conductive paste by the printing method such as letterpress printing, intaglio printing, litho printing, or screen printing can be used.

Or, well-known polymers the conductivity of which is improved by doping, for example, conductive polyaniline, conductive polypyrrole, conductive polythiophene, and complex of polyethylene dioxythiophene and polystyrene sulfonic acid are used preferably. Among them, the conductive polymers having a low electric resistance on the contact surface with the semiconductor layer are preferable.

As a metallic material (metallic fine particles) of conductive fine particles, platinum, gold, silver, cobalt, nickel, chromium, copper, iron, tin, antimony, lead, tantalum, indium, palladium, tellurium, rhenium, iridium, aluminum, ruthenium, germanium, molybdenum, tungsten, and zinc can be used, though specifically those having a work function of 4.5 eV or more such as platinum, gold, silver, copper, cobalt, chromium, iridium, nickel, palladium, molybdenum, and tungsten are preferable.

As a method for manufacturing such metallic fine-particle dispersions, the physical generation methods such as the in-gas evaporation method, sputtering method, and metallic vapor synthetic method and the chemical generation methods for reducing metallic ions in the liquid phase and generating metallic fine particles such as the colloid method and the co-precipitation method may be cited. However, metallic fine-particle dispersions manufactured by the colloid method described in JP-A H11-76800, JP-A H11-80647, JP-A H11-319538 and 2000-239853 and the in-gas evaporation method described in JP-A 2001-254185, JP-A 2001-53028, JP-A 2001-35255, JP-A 2000-124157, and JP-A 2000-123634 are preferable.

The average particle diameter of dispersed metallic fine particles is preferably 20 nm or smaller.

Further, the metallic fine-particle dispersions preferably contain a conductive polymer and when it is patterned, pressed, and heated, thus a source electrode and a drain electrode are formed, the electrodes can make ohmic contact with the organic semiconductor layer by the conductive polymer. That is, the surfaces of the metallic fine particles are surrounded by the conductive polymer, thus the contact resistance with the semiconductor is lowered, and the metallic fine particles are heated and fused, so that the effect of the present invention can be enhanced.

As a conductive polymer, a well-known conductive polymer the conductivity of which is improved by doping is used preferably and for example, conductive polyaniline, conductive polypyrrole, conductive polythiophene, and complex of polyethylene dioxythiophene and polystyrene sulfonic acid are used preferably.

The content of metallic fine particles is preferably 0.00001 to 0.1 as a mass ratio. When the mass ratio exceeds the upper limit, the fusion of the metallic fine particles may be obstructed.

When forming electrodes with these metallic fine-particle dispersions, after the source electrode and drain electrode are formed, the metallic fine particles are preferably fused by heating. Further, when forming electrodes, it is possible to apply a pressure of almost 1 to 50,000 Pa and then almost 1,000 to 10,000 Pa to the metallic fine particles to promote fusion.

As a method for patterning the aforementioned metallic fine-particle dispersions as an electrode, when patterning directly by the ink jet method, as an ejecting method of the ink jet head, the known methods such as a continuously jetting type ink jet method of an on-demand type and an electrostatic suction type such as a piezo method and a Bubble Jet (registered trademark) method can be used.

As a heating and pressurizing method, not only the method used for a heating laminator but also the well-known methods can be used.

As a gate insulating layer, various insulating films can be used, though specifically an inorganic oxide film having a high relative dielectric constant is preferable.

As an inorganic oxide, silicon oxide, aluminum oxide, tantalum oxide, titanium oxide, tin oxide, vanadium oxide, barium/strontium titanate, barium zirconate titanate, lead zirconium titanate, lead lanthanium titanate, strontium titanate, barium titanate, barium/magnesium fluoride, bismuth titanate, strontium/bismuth titanate, strontium/bismuth tantalate, bismuth tantalate niobate, and trioxide yttrium may be cited. Among them, silicon oxide, aluminum oxide, tantalum oxide, and titanium oxide are preferable. Inorganic nitrides such as silicon nitride and aluminum nitride can be used preferably.

As a forming method of the above-mentioned inorganic oxide film, the drive processes such as the vacuum deposition method, molecular beam epitaxial growth method, ion cluster beam method, low energy ion beam method, ion plating method, CVD method, sputtering method, and atmospheric pressure plasma method, the coating methods such as the spray coating method, spin coating method, blade coating method, dip coating method, casting method, roll coating method, bar coating method, and die coating method, and the wet processes such as the patterning methods of printing and ink jet may be cited and these methods can be used depending on the material.

As a wet process, a method for coating and drying a liquid obtained by dispersing fine particles of inorganic oxide in an optional organic solvent medium or water using a dispersing agent such as a surface active agent whenever necessary and the so-called sol-gel method for coating and drying an oxide precursor, for example, an alkoxide solvent are used.

Among them, the atmospheric pressure plasma method and sol-gel method are preferable.

The insulating film forming method by the plasma film forming process under the atmospheric pressure is a process of discharging under the atmospheric pressure or pressure close to the atmospheric pressure, plasma-exciting reactive gas, and forming a film on a substrate material and the method is described in JP-A H11-61406, JP-A H11-133205, JP-A 2000-121804, JP-A 2000-147209, JP-A 2000-185362 and so on. By this method, a highly functional film can be formed with high productivity.

The insulating film may be subjected to preliminarily surface treatment, examples of which are preferably above mentioned treatment by silane coupling agent, orientation treatment via rubbing and so on.

Further, polyimide, polyamide, polyester, polyacrylate, photo-setting resin of photoradical polymerization system or photocationic polymerization system, copolymer containing acrylonitrile component, polyvinyl phenol, polyvinyl alcohol, novolak resin, and cyanoethyl pullulan can be used as an organic compound film. The wet process is preferable as an organic compound film forming method,

An inorganic oxide film and an organic compound film can be laminated and used together with each other. Further, the film thickness of the insulating films is generally 50 nm to 3 μm and preferably 100 nm to 1 μm.

Further, the support is composed of glass or a flexible plastic sheet and for example, a plastic film can be used as a sheet. As a plastic film, for example, films composed of polyethylene terephthalate (PET), polyethylene naphthalate (PEN), polyether sulfone (PES), polyether imide, polyether ether ketone, polyphenylene sulfide, polyarylate, polyimide, polycarbonate (PC), cellulose triacetate (TAC), or cellulose acetate propionate (CAP) may be cited. By use of a plastic film like this, compared with a case using a glass substrate, lightweight can be realized, and the portability can be enhanced, and the shock resistance can be improved.

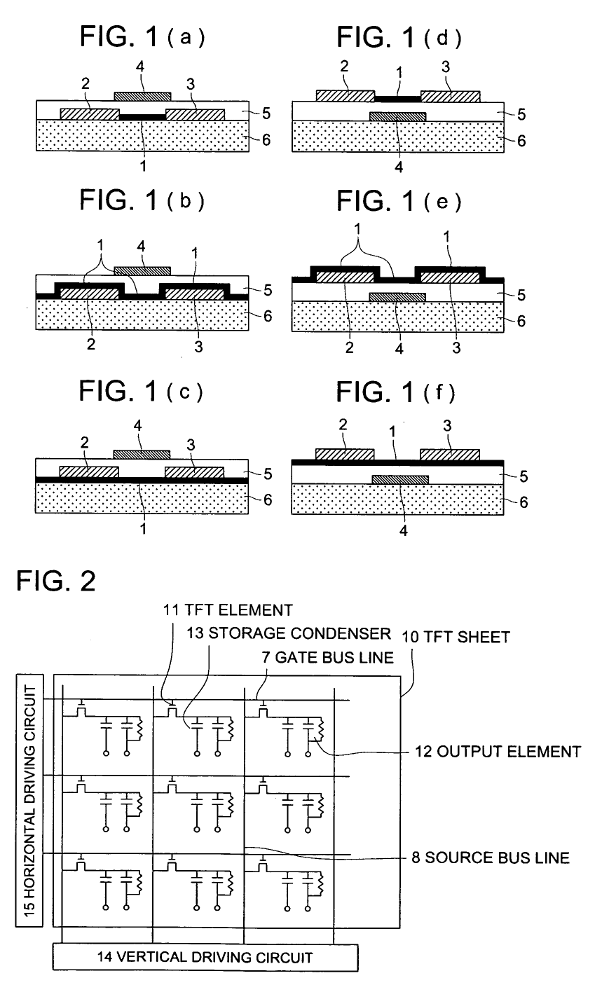

FIG. 1 shows configuration examples of the organic film transistor relating to the present invention.

In FIG. 1(a), on a glass support 6, a pattern is formed by depositing gold or others using a mask, and then h a source electrode 2 and a drain electrode 3 are formed, and an organic semiconductor material layer 1 is formed between them, and a gate insulating layer 5 is formed on it, and furthermore, a gate electrode 4 is formed on it, thus an organic TFT is formed.

FIGS. 2(b) and (c) show other configuration examples of the organic thin film transistor of the top gate type.

Further, FIGS. 2(d) through (f) show configuration examples of the organic thin film transistor (TFT) of the bottom gate type.

FIG. 2(d) shows examples that the gate electrode 4 is formed on the substrate 6, then the gate insulating layer 5 is formed, the source electrode 2 and drain electrode 3 are formed thereon, and the organic semiconductor material layer 1 is formed on the gate insulating layer between the source electrode and drain electrode, whereby an organic TFT of the bottom gate type is formed. Similarly, other configuration examples are shown in FIGS. 2(e) and 2(f). FIG. 2(f) shows an example that the gate electrode 4 is formed on the substrate 6, and then the gate insulating layer 5 is formed, and the organic semiconductor material layer 1 is formed on it, and further the source electrode 2 and drain electrode 3 are formed whereby an organic TFT of the bottom gate type is formed.

FIG. 2 is an example of a schematic equivalent circuit diagram of the TFT sheet like an output element such as a liquid crystal and cataphoresis element.

A TFT sheet 10 has a plurality of organic TFTs 11 arranged in the matrix shape. Numeral 7 indicates a gate bus line of each organic TFT 11 and 8 indicates a source bus line of each organic TFT 11. To the source electrode of each organic TFT 11, an output element 12 is connected and it is, for example, a liquid crystal or electrophoresis element and constitutes pixels on a display unit. A pixel electrode may be used as an input electrode of a photosensor. In the example shown in the drawing, a liquid crystal as an output element is represented by an equivalent circuit composed of a resistor and a capacitor. Numeral 13 indicates a storage capacitor, 14 a vertical drive circuit, and 15 a horizontal drive circuit.

### EXAMPLES

Specifically, the present invention will be described with reference to examples, however the present invention is not limited thereto.

### Comparative Example 1

After forming a 200 nm thick thermally oxidized film on an n type Si wafer of a specific resistance of 0.02 Ω·cm, the surface was cleaned via an oxygen plasma treatment, whereby a gate insulation film was prepared.

Subsequently, as a semiconductor material written on another paper, 0.1 weight % solution of Exemplified Compound <9> employing the solvent in Table 1 was prepared. By carrying out N₂ gas bubbling, dissolved oxygen in the solution was removed and in an ambience of N₂ gas, coating was carried out on the surface of the above silicon oxide film, followed by drying under reduced pressure.

Further, gold was subjected to vapor deposition onto the surface of the resulting film, employing a mask, whereby a source electrode and a drain electrode were formed. Based on the above, an organic thin-film transistor of channel length L of 30 μm and channel width W of 1 mm was prepared. The resulting transistor preferably worked as a p channel channel enhancement type FET. The carrier mobility of these transistors in the saturation region was calculated based on I-V characteristics.

### Example 1

A 200 nm thick thermally oxidized film was formed on an n type Si wafer of a specific resistance of 0.02 Ω·cm. Thereafter, the above film was employed as a gate insulation film, and a thin film transistor was prepared in the same manner as Comparative Example 1. Performance of the resulting transistor as FET was determined in the same manner.

### Example 2

After forming a 200 nm thick thermally oxidized film (SiO₂) as a gate insulation layer on an n type Si wafer of a specific resistance of 0.02 Ω·cm, hexamethyldisilazane (HMDS) was coated via spin coating. The resulting coating was subjected to a surface treatment via heating at 80° C. for 30 minutes. Subsequently, an organic semiconductor layer was formed in the same manner as Example 1 and further, source and drain electrodes were formed, whereby a thin-film transistor was prepared.

Performance as FET was determined in the same manner as for the Comparative Example.

### Example 3

A 200 nm thick thermally oxidized film (SiO₂) was formed on an n type wafer of a specific resistance of 0.02 Ω·cm, and subsequently was immersed in a toluene solution (1% by weight) of octyltrichlorosilane (OTS) for 10 minutes. Thereafter, rinsing was carried out employing toluene, and the resulting thermally oxidized film was subjected to a surface treatment via drying, whereby a gate insulation film was prepared. Subsequently, in the same manner as Example 1, an organic semiconductor layer was formed and further, source and drain electrodes were formed, whereby a thin-film transistor was prepared. FET performance was determined in the same manner as for the Comparative Example.

Each of the contact angles (at 20° C.) of n-hexane, methylene iodide, and water was determined for Comparative Example 1 and Examples 1-3, namely the 200 nm thermally oxidized film (SiO₂) surface formed on the above Si wafer (Example 1), the surface which was subjected to an HMD treatment on the surface of the 200 nm thermally oxidized film (SiO₂) formed on the above Si wafer (Example 2), the thermally oxidized film (SiO₂) surface which was subjected to a surface treatment employing octyltrichlorosilane (OTS) (Example 3), and the surface- formed by applying an oxygen plasma treatment to the 200 nm thermally oxidized film (SiO₂) surface formed on the above Si wafer (Comparative Example 1). Based on non-polar component γ_{L}^{d}, polar component γ_{L}^{p}, and hydrogen bond component γ_{L}^{h} of each surface free energy, each of components γ_{S}^{d}, γ_{S}^{p}, and γ_{S}^{h} of surface free energy of each solid surface was calculated (Table 1).

On the other hand, the surface free energy (at 20° C.) of each of the solvents employed in the coating liquid composition was referred to page 33 of Toshio Ishii, Shinjun Koishi, and Mitsuo Kakuta, “Nure Gijutsu Handbook—Kiso•Sokutei Hyoka Data—(Wetting Technology Handbook—Basis•Measurement Evaluation Data—)” (some are listed in Table 2).

In Table 3, summarized are (values at 20° C.) carrier mobility in the saturated region obtained from the I-V characteristics of these transistors prepared in Comparative Example 1 and Examples 1-3 and the difference in each component between the surface energy of the employed substrate and the surface energy of the solvents employed in the organic semiconductor material solution, namely hydrogen bond component of the surface free energy of a substrate)−hydrogen bond component of the surface free energy of solvents).

TABLE 1

| | Surface Free Energy of Solid (mN/m) | | |
|---|---|---|---|
| | γS^{d} | γS^{p} | γS^{h} |
| OTS Treatment | 23.2 | 2.1 | 0.1 |
| HMDS Treatment | 25.0 | 3 | 1 |
| SiO₂ | 39.3 | 4.5 | 19.3 |
| SiO₂(O₂) | 40.6 | 4.3 | 30.9 |

TABLE 2

| | Surface Free Energy of Solvent (mN/m) | | |
|---|---|---|---|
| | γL^{d} | γL^{p} | γL^{h} |
| Chloroform | 18.16 | 3.13 | 5.85 |
| o-Dichlorobenzene | 17.86 | 5.92 | 3.06 |
| Toluene | 23.92 | 1.90 | 2.71 |
| Hexane | 18.4 | 0.00 | 0.00 |
| Cyclohexane | 24.38 | 0.00 | 0.00 |
| Tetrahydrofuran (THF) | 14.54 | 4.95 | 6.90 |

TABLE 3

| | Comparative | | | |
|---|---|---|---|---|
| | Example 1; | Example 1; | Example 2; | Example 3; |
| | SiO₂(O₂) | SiO₂ | HMDS | OTS |
| | Mobility (μ) | Mobility (μ) | Mobility (μ) | Mobility (μ) |
| | γS^{h} − γL^{h} | γS^{h} − γL^{h} | γS^{h} − γL^{h} | γS^{h} − γL^{h} |
| Chloroform | at most 10⁻⁵ | 0.0005 | 0.08 | impossible to |
| | | | | prepare film |
| | 25.0 | 13.5 | −4.9 | −5.7 |
| o-dichloro- | at most 10⁻⁵ | 0.0005 | 0.05 | 0.1 |
| benzene | 27.8 | 16.3 | −2.1 | −2.9 |
| Toluene | at most 10⁻⁵ | 0.0005 | 0.05 | 0.1 |
| | 28.1 | 16.6 | −1.7 | −2.6 |
| Hexane | at most 10⁻⁵ | 0.0005 | 0.01 | 0.01 |
| | 30.9 | 19.3 | 1.0 | 0.1 |
| Cyclohexane | at most 10⁻⁵ | 0.0005 | 0.01 | 0.01 |
| | 30.9 | 19.3 | 1.0 | 0.1 |
| Tetrahydro- | at most 10⁻⁵ | 0.001 | impossible to | impossible to |
| furan | | | prepare film | prepare film |
| (THF) | 24.0 | 12.4 | −5.9 | −6.8 |
| THF:cyclo- | at most 10⁻⁵ | 0.0008 | 0.02 | 0.08 |
| hexane = 2:8 | 29.5 | 18.0 | −0.4 | −1.2 |

Unit of surface free energy: mN/m
THF:cyclohexane = 2:8 in volume ratio

When the difference between the hydrogen bond component of the surface free energy of the gate insulation film and the hydrogen bond component of the surface free energy of solvents employed in the organic semiconductor material solution is within the range described in claim 1, and the hydrogen bond component of the surface free energy of the substrate is within the range of claim 1, it is found that the carrier mobility of prepared organic thin-film transistors is high. Specifically, when the substrate surface has been subjected to the surface treatment, the resulting transistors exhibit high carrier mobility and exhibit desired characteristics as a p channel enhancement type TFT.

1. A method for forming a thin semiconductor material film by coating a liquid composition containing an organic semiconductor material onto a surface of a substrate, wherein when a surface free energy of the above substrate surface is represented by γₛ=γ_{S}^{d}+γ_{S}^{p}+γ_{S}^{h} (wherein γ_{S}^{d}, γ_{S}^{p}, and γ_{S}^{h} each represent a non-polar component, a polar component, and a hydrogen bond component of the surface free energy of the solid surface based on the Young-Fowkes equation), and a surface free energy of a solvent in the liquid is represented by γ_{L}=γ_{L}^{d}+γ_{L}^{p}+γ_{L}^{h} (wherein γ_{L}^{d}, γ_{L}^{p}, and γ_{L}^{h} each represent a non-polar component, a polar component, and a hydrogen bond component of the surface free energy of liquid based on the Young-Fowkes equation), γ_{S}^{h}−γ_{L}^{h} value is in the range of −5 to 20 (mN/m) and hydrogen bond component γ_{S}h is 0<γ_{S}^{h}<20 (mN/m).

2. The thin organic semiconductor material film forming method of claim 1, wherein the surface of the substrate has been subjected to a surface treatment.

3. The thin organic semiconductor material film forming method of claim 1 wherein the hydrogen bond component of the surface free energy of the substrate surface γ_{S}^{h} is 0<γ_{S}^{h}<15 (mN/m).

4. The thin organic semiconductor material film forming method of claim 2, wherein the surface treatment employs a silane coupling agent.

5. The thin organic semiconductor material film forming method of claim 1, wherein the solvent in the liquid composition containing organic semiconductor material is a non-halogenated solvent.

6. The thin organic semiconductor material film forming method of claim 1, wherein a weight average molecular weight of the organic semiconductor material is at most 5,000.

7. An organic thin-film transistor production method comprising the thin organic semiconductor material film forming method of claim 1, wherein the organic semiconductor material is a compound containing a thiophene ring.

8. The organic thin-film transistor production method of claim 1, wherein the organic semiconductor material is a compound having an alkylthiophene ring.
